(19) United States
(12) Patent Application Publication
(10) Pub. No.: US 2006/0115915 A1
(43) Pub. Date: Jun. 1, 2006

(54) Method of manufacturing electrooptical device and image forming device

(75) Inventor: Katsuhiro Takahashi, Shiojiri (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/256,604

(22) Filed: Oct. 21, 2005

(30) Foreign Application Priority Data
Nov. 29, 2004 (JP) 2004-343425

(51) Int. Cl. H01L 21/00

(52) U.S. Cl. 438/27

(57) ABSTRACT

A method of manufacturing an electrooptical device includes a step of forming a luminous element on a luminous element forming face of a transparent substrate, a step of forming an attach face by grinding a face of the transparent substrate that opposes the luminous element forming face toward the luminous element forming face side after attaching a support substrate to the transparent substrate on the luminous element forming face side and a step of providing the microlens that sends out a light emitted from the luminous element on the transparent substrate with a sheet substrate therebetween by attaching a side face of the sheet substrate opposing a lens forming face on which the microlens is formed to the attach face.

### BACKGROUND OF THE INVENTION

1. Technical Field

The present invention relates to a method of manufacturing an electrooptical device and an image forming device.

2. Related Art

In an image forming device employing an electrophotographic method, an exposure head is used as an electrooptical device forming a latent image by exposing a photoconductive drum that is an image retainer. In recent years an organic electroluminescence (EL) element has been proposed as a light source for the exposure head in order to reduce thickness and weight of the exposure head.

In particular, a so-called bottom emission structure is adopted for the exposure head because it has an advantage of wide range of constituent material choice. The bottom emission structure is a structure in which the organic EL element is formed on an one side of a transparent substrate (a face where a luminous element is formed) and a light emitted from the organic EL element is taken out from the other face (a light takeoff face) that opposes the face where the luminous element is formed.

In the bottom emission structure, various wirings and capacitors for making the organic EL elements emit light are formed between the light takeoff face and the organic El elements. For this reason, there was a problem that an aperture ratio of the EL element decreases, making light takeoff efficiency low.

In order to increase the light takeoff efficiency, a so-called microlens that collects the light emitted from the organic EL elements has been proposed for this kind of the exposure head to be provided on the light takeoff face. JP-A-1-123456 is an example of related art. The example describes that an indurative resin is discharged on the light takeoff face opposing the organic EL element and the discharged resin is indurated to form the microlens.

In the above-described exposure head, however, the microlens is placed apart from the organic EL element with the distance between the face where the luminous element is formed and the light takeoff face, in other words, with the distance which is a thickness of a transparent substrate. Thereby, an angular aperture of the microlens against the organic EL element (the angle from the center position of the organic EL element toward the diameter of the microlens) decreases by the thickness of the transparent substrate, leading to the problem of impairing the light takeoff efficiency of the light emitted from the organic EL element.

Such problem could be reduced by thinning the transparent substrate and forming the organic EL element and the microlens on the thin substrate. However, when the thickness of the transparent substrate is reduced, its mechanical strength is also reduced. Therefore, the transparent substrate could be broken off when the organic EL element and the microlens are formed. Furthermore, it becomes difficult to perform a process making the light takeoff face of the transparent substrate smooth. The roughness of the surface (arithmetic average roughness) could cause variation in the forming position or the shape of the microlens.

### SUMMARY

An advantage of the invention is to provide a method of forming an electrooptical device in which the light takeoff efficiency of the light emitted from a luminous element is improved and the variation in the forming position or the shape of the microlens is prevented. Another advantage of the invention is to provide an image formation device thereof.

According to a first aspect of the invention, a method of manufacturing an electrooptical device includes a step of forming a luminous element on a luminous element forming face of a transparent substrate, a step of forming an attach face by grinding a face of the transparent substrate that opposes the luminous element forming face toward the luminous element forming face side after attaching a support substrate to the transparent substrate on the luminous element forming face side and a step of providing the microlens that sends out a light emitted from the luminous element on the transparent substrate with a sheet substrate therebetween by attaching a side face of the sheet substrate opposing a lens forming face on which the microlens is formed to the attach face.

According to the first aspect of the invention, the attach face can be placed closer to the luminous element forming face by grinding the face opposing the luminous element forming face. Moreover, since the microlens is formed on the lens forming face of the sheet substrate, the variation in the forming position or the shape of the microlens is prevented compared with a case that the microlens is formed on the attach face which is formed by grinding. Accordingly, the variation in the forming position or the shape of the microlens is prevented as much as grinding more than the thickness of the sheet substrate. Therefore, an aperture angle of the microlens can be increased and it is possible to manufacture the electrooptical device with which the light takeoff efficiency of the light emitted from the luminous element is improved.

In this case, the microlens may be provided on the transparent substrate by attaching the side face of the sheet substrate to the attach face after the microlens is formed on the lens forming face of the sheet substrate.

The sheet substrate having the microlens formed on the lens forming face is attached to the attach face in the above-mentioned case. Thereby, it is possible to avert damage to the luminous element by various processes such as ultraviolet irradiation for forming the microlens and a heat treatment.

The microlens may be provided in a plural number and formed on the lens forming face, each microlens is placed so as to oppose the corresponding luminous element by attaching the side face of the sheet substrate to the attach face.

It is possible to securely improve the light takeoff efficiency of the light emitted from each luminous element because each microlens is placed so as to oppose the corresponding luminous element.

The attach face may be formed by grinding the face of the transparent substrate.

In this way, the distance between the luminous element forming face and the attach face can be decreased by the grinding of the transparent substrate face. Accordingly, it is possible to manufacture the electrooptical device in which the light takeoff efficiency of the light emitted from the luminous element is improved.

Alternatively, the attach face may be formed by etching the face of the transparent substrate.

In this way, the distance between the luminous element forming face and the attach face can be decreased by the etching amount of the transparent substrate face. Accordingly, it is possible to manufacture the electrooptical device in which the light takeoff efficiency of the light emitted from the luminous element is improved.

A droplet may be formed on the lens forming face by discharging functional liquid from a droplet discharge device, and the microlens may be formed by indurating the droplet.

In this way, since the microlens is formed by discharging the functional liquid from the droplet discharge device, the microlens 40 can be formed without any limitation for the thickness of the transparent substrate. As a result, it is possible to manufacture the electrooptical device in which the light takeoff efficiency of the light emitted from the luminous element is improved.

Furthermore, the droplet having a semispherical shape may be formed on the lens forming face at a position opposing the luminous element, and the convex shaped microlens may be formed by indurating the droplet.

In this way, the microlens is formed in the concave shape. Thereby, it is possible to improve an efficiency to condense the light emitted from the luminous element with the microlens. As a result, it is possible to simply manufacture the electrooptical device in which the light takeoff efficiency is improved.

In this case, the luminous element may be an electroluminescence element having a transparent electrode formed on the attach face side, a back electrode formed so as to oppose the transparent electrode, and an emissive layer formed between the transparent electrode and the back electrode.

In the above-mentioned case, it is possible to manufacture the electrooptical device in which the light takeoff efficiency of the light emitted from the electroluminescence element is improved.

The emissive layer may be made of an organic material and the electroluminescence element is an organic electroluminescence element.

In this way, it is possible to manufacture the electrooptical device in which the light takeoff efficiency of the light emitted from the organic electroluminescence element is improved.

According to a second aspect of the invention, an image forming device includes a charge unit charging a peripheral surface of an image retainer, an exposure unit exposing the charged peripheral surface of the image retainer and forming a latent image, a develop unit developing the image into a developed image by supplying a colored particle to the latent image and a transfer unit transferring the developed image to a transfer medium, wherein the exposure unit is the above-described electrooptical device.

According to the second aspect of the invention, the exposure unit exposing the charged image retainer has the above-described electrooptical device. Therefore, it is possible to improve the light takeoff efficiency in the exposure in the image forming device.

### BRIEF DESCRIPTION OF THE DRAWINGS

The invention will be described with reference to the accompanying drawings, wherein like numbers reference like elements.

FIG. 1 is a schematic sectional side view of an image forming device according to an embodiment of the invention.

FIG. 2 is a schematic sectional view of an exposure head.

FIG. 3 is a schematic plan view of the exposure head.

FIG. 4 is an enlarged sectional view of the exposure head.

FIG. 5 is a flow chart showing a manufacturing process of the exposure head.

FIG. 6 is an explanatory drawing for explaining the manufacturing process of the exposure head.

FIG. 7 is an explanatory drawing for explaining the manufacturing process of the exposure head.

FIG. 8 is an explanatory drawing for explaining the manufacturing process of the exposure head.

FIG. 9 is an explanatory drawing for explaining the manufacturing process of the exposure head.

### DESCRIPTION OF THE EMBODIMENTS

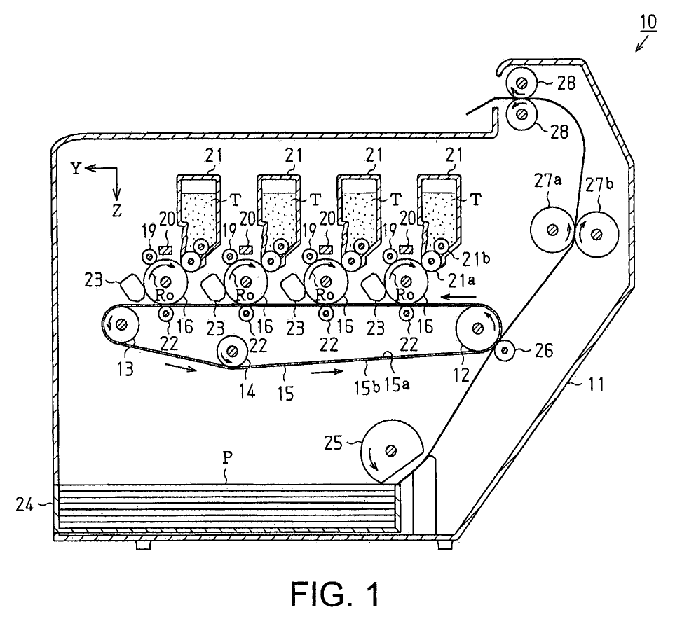

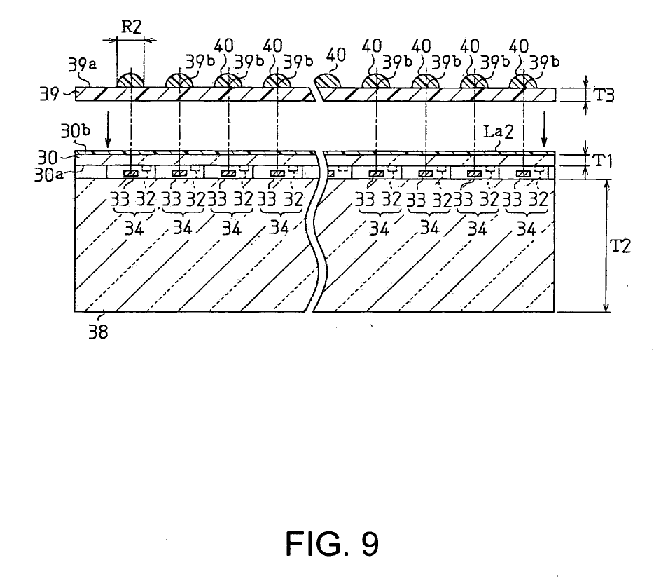

An embodiment of the invention is now described with reference to FIG. 1 through FIG. 9. FIG. 1 is a schematic sectional side view of an electrophotographic printer which is a kind of an image forming device.

Electrophotographic Printer

As shown in FIG. 1, an electrophotographic printer 10 (hereinafter simply called “printer 10”) has a case 11 that has a box shape. A driving roller 12, a driven roller 13 and a tension roller 14 are provided in the case 11. An intermediate transfer belt 15 which is a transfer medium is set up across the rollers 12 though 14. The intermediate transfer belt 15 is provided so as to be cyclically driven in the direction of the arrow shown in FIG. 1 by the rotation of the driving roller 12.

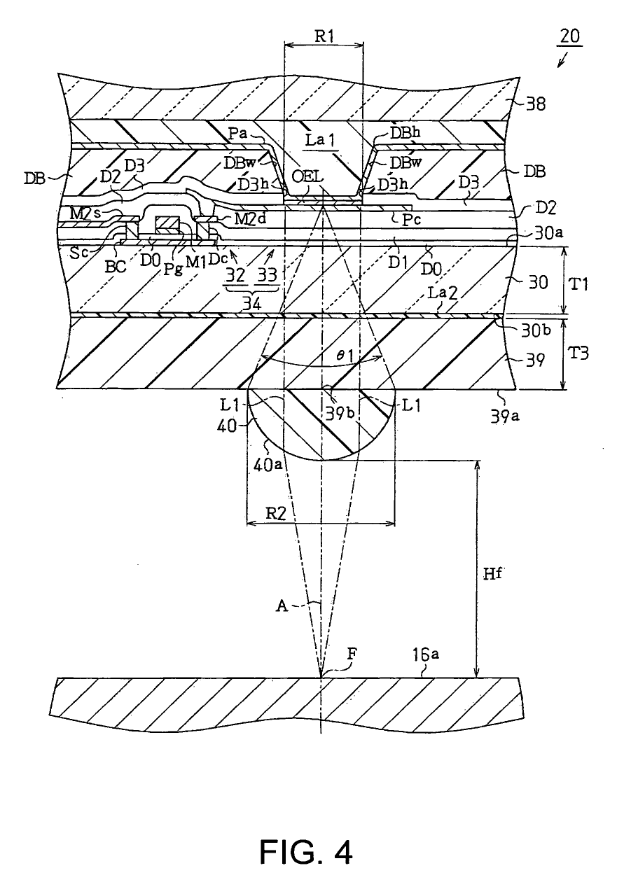

Above the intermediate transfer belt 15, four photoconductive drums 16 are provided side by side so as to be rotatable in the direction (sub scanning direction Y) the intermediate transfer belt 15 is set up. A photosensitive layer 16a (see FIG. 4) having photoconductivity is formed on a peripheral face of the photoconductive drum 16. The photosensitive layer 16a is positively or negatively charged in the dark. When the layer is irradiated with a light of a predetermined wavelength, the charges positioned at a part where is irradiated is vanished. In other words, the electrophotographic printer 10 is a tandem printer consisting of the four photoconductive drums 16.

A charged roller 19 which is a means of charging, an organic electroluminescence-array exposure head 20 (hereinafter simply called “exposure head 20”) which is an electrooptical device and a means of exposing, a toner cartridge 21 which is a means of developing, a first transfer roller 22 which is a means of transferring and a cleaning means 23 are provided around each photoconductive drum 16.

The charged roller 19 is a semiconductive rubber roller that is closely attached to the photoconductive drum 16. When a direct-current voltage is applied to the charged roller 19 and the photoconductive drum 16 rotates, the whole photosensitive layer 16a of the photoconductive drum 16 is charged with a predetermined charge potential.

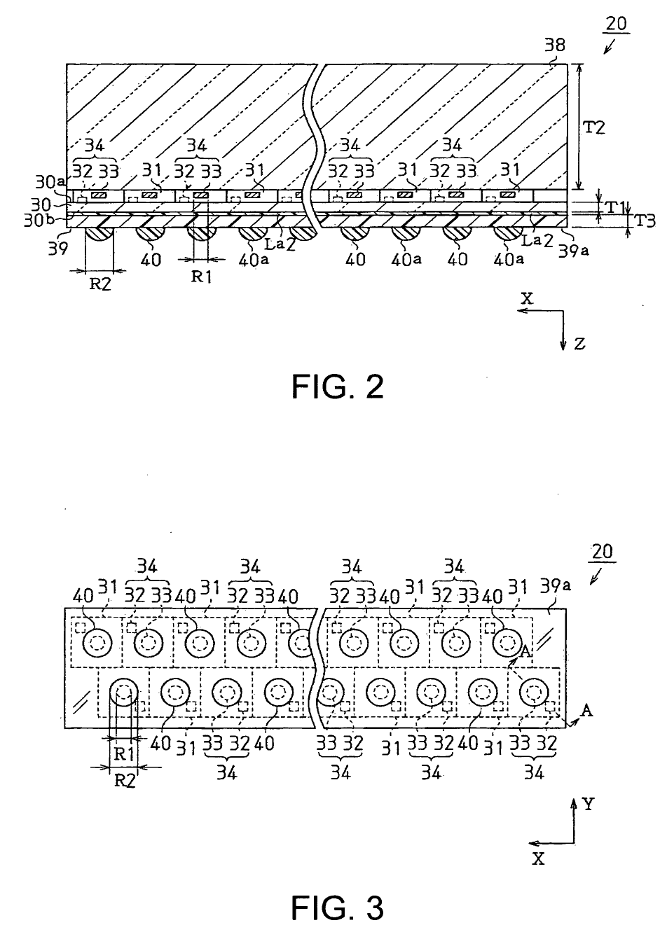

The exposure head 20 is a light source emitting a predetermined wavelength light and formed to have a long plate shape as shown in FIG. 2. The longer side of the exposure head 20 is parallel to a direction of the axis of the photoconductive drum 16 (the orthogonal direction to the page of FIG. 1 or a main scanning direction X). The exposure head 20 is placed at a predetermined position at a predetermined distance from the photosensitive layer 16a. When the exposure head 20 emits the light that depends on a printing data in a vertical direction Z (see FIG. 1) and the photoconductive drum 16 rotates in a rotation direction Ro, the photosensitive layer 16a is exposed with the predetermined wavelength light. The photosensitive layer 16a then loses the charges placed at a part where is exposed (an exposure spot) and an electrostatic image (electrostatic latent image) is formed on the peripheral face of the layer. Here, a wavelength range of the light used for exposure of the exposure head 20 is consistent with the spectral sensitivity of the photosensitive layer 16a. In other words, a peak wavelength of the light energy of the light emitted by the exposure head 20 is substantially the same as that of the spectral sensitivity of the photosensitive layer 16a.

The toner cartridge 21 is formed to have a case shape and contains a toner T which is colorant particles. The diameter of each particle is about 10 μm. The four toner cartridges 21 in this embodiment respectively contain corresponding four different color (black, cyan, magenta and yellow) toners T. A develop roller 21a and a supply roller 21b are provided on the toner cartridge 21 in this order from the photoconductive drum 16 side. The supply roller 21b rotates to convey the toner T to the develop roller 21a. The develop roller 21a electrically charges the toner T conveyed by the supply roller 21b by friction with the supply roller 21. The charged toner T evenly adheres to the peripheral surface of the develop roller 21a.

Next, a bias potential that is substantially the same as the above-mentioned charge potential is applied to the photoconductive drum 16, and the supply roller 21b and the develop roller 21a are rotated. The photoconductive drum 16 gives electrostatic adhesion, which is opposite to the above-mentioned bias potential, to between the above-mentioned exposure spot and the develop roller 21a (toner T). The toner T that received the electrostatic adhesion moves to the above-mentioned exposure spot from the peripheral face of the develop roller 21a and sticks there. Thereby, a unicolor visible image (developed image) corresponding to the electrostatic latent image is formed (developed) on the peripheral face of each photoconductive drum 16 (a photosensitive layer 16a).

The first transfer roller 22 is provided so as to oppose the photoconductive drum 16 on an inner face 15a of the intermediate transfer belt 15. The first transfer roller 22 is a conductive roller rotating as whose peripheral face closely contacts with the inner face 15a of the intermediate transfer belt 15. When the photoconductive drum 16 and intermediate transfer belt 15 are rotated by applying a direct-current voltage to the first transfer roller 22, the toner T that is stuck to the photosensitive layer 16a sequentially moves and attaches to an outer face 15b of the intermediate transfer belt 15 by the electrostatic adhesion toward the first transfer roller 22 side. In other words, the first transfer roller 22 primarily transfers the developed image formed on the photoconductive drum 16 to the outer face 15b of the intermediate transfer belt 15. This primary transfer of the unicolor developed image is repeated four times to the outer face 15b of the intermediate transfer belt 15 by the each photoconductive drum 16 and the first transfer roller 22. A full color image (a toner image) is obtained by superposing these developed images.

The cleaning means 23 has an unshown light source such as a LED and a rubber blade. The cleaning means 23 removes the electricity from the charged photosensitive layer 16a by irradiating light to the photosensitive layer 16a after the above-mentioned primary transfer is performed. The cleaning means 23 also mechanically removes the toner T that is remained on the charge removed photosensitive layer 16a with its rubber blade.

A record paper cassette 24 holding a record paper P is provided under the intermediate transfer belt 15. Above the record paper cassette 24, a paper feed roller 25 is placed so as to feed the record paper P to the intermediate transfer belt 15 side. A secondary transfer roller 26 which is a part of the transfer means is provided above the paper feed roller 25 so as to oppose the driving roller 12. The secondary transfer roller 26 is the conductive roller that is same as the first transfer roller 22. The secondary transfer roller 26 presses the back of the record paper P, making the front of the record paper P contact with the outer face 15b of the intermediate transfer belt 15. When the intermediate transfer belt 15 is rotated by applying a direct-current voltage to the secondary transfer roller 26, the toner T that is stuck to the outer face 15b of the intermediate transfer belt 15 sequentially moves and attaches to the surface of the record paper P. In other words, the secondary transfer roller 26 secondary transfers the toner image formed on the outer face 15b of the intermediate transfer belt 15 to the surface of the record paper P.

A heat roller 27a having a heat source and a press roller 27b pressing the heat roller 27a are provided above the secondary transfer roller 26. When the secondary transferred record paper P is taken between the heat roller 27a and the press roller 27b, the toner T transferred on the record paper P is turned soft by heat and then penetrates into the record paper P, being indurated there. In this way, the toner image is fixed on the surface of the record paper P. The record paper P on which the toner image is fixed is passed out from the case 11 by a paper ejection roller 28.

As described above, the printer 10 exposes the charged photosensitive layer 16a with the exposure head 20 and forms the electrostatic latent image on the photosensitive layer 16a. The printer 10 then develops the electrostatic latent image on the photosensitive layer 16a and forms the unicolor visible image on the photosensitive layer 16a. Subsequently, the printer 10 primarily transfers the developed image of the photosensitive layer 16a to the intermediate transfer belt 15 in order of precedence and forms the full color toner image on the intermediate transfer belt 15. The printer 10 then secondarily transfers the toner image on the intermediate transfer belt 15 to the record paper P, fixes the toner image by heat and pressing, and finishes off the printing.

Next, the exposure head 20 which is the electrooptical device equipped in the above-described printer 10 is now described. FIG. 2 is a sectional view of the exposure head 20.

As shown in FIG. 2, the exposure head 20 has an element substrate 30 which is a transparent substrate. The element substrate 30 is a long clear colorless non-alkali glass substrate, and a width of its longer side (the horizontal direction in FIG. 2 or the main scanning direction X) is substantially the same as the width of the photoconductive drum 16 in its axis direction.

The thickness of the element substrate 30 is set on the ground that a uniform thickness (an after-grinding thickness T1) is obtained by a hereinafter described grinding step. The after-grinding thickness T1 is 50 μm in this embodiment, however, the thickness T1 is not particularly limited.

Furthermore, in this embodiment, the upper face (opposite face to the photoconductive drum 16 side) of the element substrate 30 is a luminous element forming face 30a, and an under surface that will be formed in the later-described grinding step (face of the photoconductive drum 16 side) is an attach face 30b.

Firstly, the luminous element forming face 30a side of the element substrate 30 is described. FIG. 3 is a plan view of the exposure head viewing from the attach face 30b. FIG. 4 is a schematic sectional view of the exposure head along with the dashed line A-A in FIG. 3.

A plurality of pixel forming regions 31 is formed on the luminous element forming face 30a of the element substrate 30 as shown in FIG. 2. The pixel forming regions 31 are arranged in a plane in a hound's tooth pattern as shown in FIG. 3. Each pixel forming region 31 has a pixel 34 consisting of a thin film transistor 32 (hereinafter called “TFT 32”) and an organic electroluminescence element 33 (an organic EL element) that is the luminous element. The TFT 32 is turned on by a data signal that is generated based on the printing data. The organic EL element 33 produces light according to the ON state of the TFT.

The TFT 32 has a channel film BC as its bottom layer as shown in FIG. 4. The channel film BC is a p-type polysilicon film having an island shape formed on the luminous element forming face 30a. Unshown activated n-type region (a source region and a drain region) is formed on the both sides of the p-type polysilicon film. In other words, the TFT 32 is so called polysilicon type TFT.

Above the center of the channel film BC, a gate insulating film D0, a gate electrode Pg and a gate wiring M1 are formed in this order from the luminous element forming face 30a side. The gate insulating film D0 is an insulating film having light transparency such as a silicon oxide film and the like, and deposited on the channel film BC and substantially the whole area of the luminous element forming face 30a. The gate electrode Pg is a low-resistance metal film such as tantalum and formed so as to oppose substantially the center of the channel film BC. The gate wiring M1 is a transparent conductive film such as indium tin oxide (ITO) and electrically couples the gate electrode Pg and an unshown data line driving circuit. When the data line driving circuit inputs a data signal to the gate electrode Pg through the gate wiring M1, the TFT 32 becomes the ON state based on the data signal.

A source contact Sc and a drain contact Dc extending upward are formed on the channel film BC and above the source region and the drain region. Contacts Sc and Dc are formed of a metal film in order to reduce the contact resistance with the channel film BC. The contacts Sc, Dc and the gate electrode Pg (the gate wiring M1) are electrically isolated by a first interlayer insulating film D1 that is made of the silicon oxide film and the like.

A power wire M2s and a positive electrode line M2d that are made of the low-resistance metal film are respectively formed the contact Sc and the contact Dc. The power wire M2s electrically couples the source contact Sc with an unshown driving power supply. The positive electrode line M2d electrically couples the drain contact Dc with the organic EL element 33. These power wire M2s and the positive electrode line M2d are electrically isolated by a second interlayer insulating film D2 that is made of the silicon oxide film and the like. When the TFT 32 becomes the ON state based on the data signal, a driving current corresponding to the data signal is supplied to the positive electrode line M2d (the organic EL element 33) from the power wire M2s (the driving power supply).

The organic EL element 33 is formed above the second interlayer insulating film D2 as shown in FIG. 4. A transparent cathode Pc is formed as the bottom layer of the organic EL element 33. The cathode Pc is the transparent conductive film such as the ITO and its one end is coupled to the positive electrode line M2d.

A third interlayer insulating film D3 made of the silicon oxide film and the like that electrically isolates each cathode Pc is deposited on the cathode Pc. A round opening (a position alignment opening D3h) that opens upward at substantially the center of the cathode Pc is formed in the third interlayer insulating film D3. Though the diameter of the position alignment opening D3h which is denoted as an alignment diameter R1 is 50 μm, the diameter is not particularly limited.

A partition wall layer DB made of resin such as photosensitive polyimide is deposited on the third interlayer insulating film D3. A conical opening DBh that opens upward in a taper shape at a position opposing the position alignment opening D3h is formed in the partition wall layer DB. An inner peripheral face of the conical opening DBh forms a partition wall DBw.

An organic electroluminescence layer OEL (organic EL layer) made of a kind of polymer organic material is formed inside the position alignment opening D3h and on the cathode Pc. More specifically, the organic EL layer OEL is formed so as to have an outline whose diameter is same as that of the position alignment opening D3h (the alignment diameter R1).

The organic EL layer OEL is an organic compound layer consisting of a hole transfer layer and an emissive layer. An anode Pa which is a back electrode made of a metal film having light reflectivity such as aluminum is formed on the organic EL layer OEL. The anode Pa is formed so as to cover substantially the whole surface of the luminous element forming face 30a side. The anode Pa is shared by each pixel 34, and a common electric potential is provided to each organic EL element 33.

As described above, the organic EL element 33 is the organic electroluminescence element (organic EL element) consisting of the cathode Pc, the organic EL layer OEL and the anode Pa, and has a light emitting face (the organic EL layer OEL) whose diameter is an inside diameter of the position alignment opening D3h, in other words, the alignment diameter R1 (50 μm).

A support substrate 38 that is attached to the anode Pa (element substrate 30) with an adhesion layer La1 is provided over the anode Pa. The support substrate 38 is a colorless clear non-alkali glass substrate having the same size as that of the element substrate 30 when it is viewed in a plane. The support substrate 38 has an enough thickness (support thickness T2) to obtain mechanical strength of the exposure head 20. The support thickness T2 of the support substrate 38 is 500 μm in this embodiment, however, the thickness T2 is not particularly limited.

When the driving current corresponding to the data signal is supplied to the positive electrode line M2d, the organic EL layer OEL emits light with brightness depending on the driving current. The light emitted from the organic EL layer OEL toward the anode Pa side (upward in FIG. 4) is reflected by the anode Pa. Therefore, most of the light penetrates the cathode Pc, the second interlayer insulating film D2, the first interlayer insulating film D1, the gate insulating film D0 and the element substrate 30, and then exits to the attach face 30b side (the photoconductive drum 16 side).

Next, the attach face 30b side of the element substrate 30 is described.

A sheet substrate 39 is provided on the attach face 30b of the element substrate 30 with the adhesion layer La2 therebetween as shown in FIG. 2. The adhesion layer La2 is a layer made of ultraviolet curing resin and the like and boding the attach face 30b and the sheet substrate 39. The sheet substrate 39 is a polyimide sheet whose surface roughness (an arithmetic average roughness Ra) is less than 1 μm and whose thickness (a sheet thickness T3) is the same as the after-grinding thickness T1 (50 μm).

A microlens 40 is formed on a lens forming face 39a at a position opposing each organic EL element 33 as shown in FIG. 2. The microlens 40 is a convex shape lens having a hemispherical optical surface and an enough light transmissivity for the wavelength of the light emitted from the organic EL layer OEL. The microlens 40 is formed such that the center of the organic EL element 33 (the organic EL layer OEL) lays on a light axis A as shown in FIG. 4.

In this embodiment, the diameter (an aperture diameter R2) of the microlens 40 is twice as large as the diameter (the alignment diameter R1) of the organic EL layer OEL, in other words, the diameter of the microlens 40 is 100 μm. Thereby, the microlens 40 can transmit the light emitted from the organic EL layer OEL toward the lens forming face 39a side without impairing its imaging quality around the peripheral.

Furthermore, the microlens 40 has an image side focal length Hf which is a distance between the top of an inferior curved surface (an emission face 40a) and the photosensitive layer 16a so that an intersection between light beams (a parallel light beams L1) emitted from the organic EL element 33 along with the light axis A can be planed on the photosensitive layer 16a. Thereby, the light emitted from the microlens 40 can form the exposure spot with a desired size on the photosensitive layer 16a.

In this embodiment, an angle formed by the center of the organic EL layer OEL and the diameter of the microlens 40 is defined as an aperture angle θ1.

Method Of Manufacturing Exposure Head

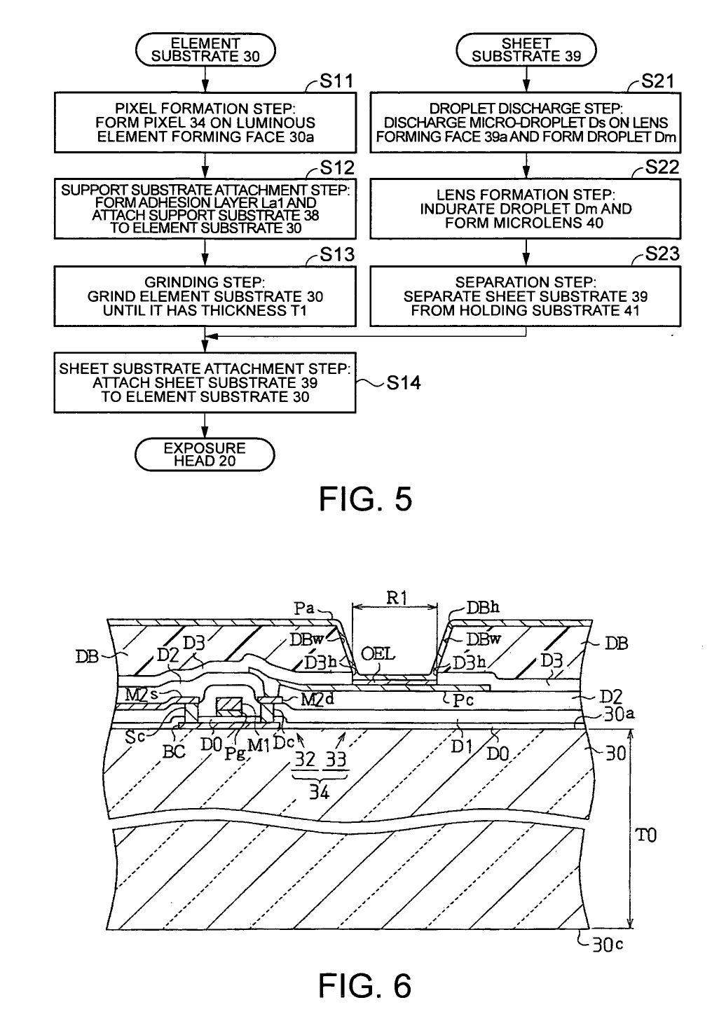

Next, the method of manufacturing the exposure head 20 is now described. FIG. 5 is a flow chart showing the manufacturing method of the exposure head. FIG. 6 through FIG. 9 are explanatory drawings for explaining the manufacturing method of the exposure head.

Firstly, a pixel formation step (Step 11 or S11) in which the pixel 34 is formed on the luminous element forming face 30a of the element substrate 30 is performed as shown in FIG. 5.

Here, the thickness of the element substrate 30 is a before-grinding thickness T0 which is larger than the after-grinding thickness T1 and has an enough mechanical strength for a heat treatment and a plasma treatment and the like in the hereinafter-described pixel formation step. Though the before-grinding thickness T0 is 500 μm in this embodiment, the thickness T0 is not particularly limited.

In the pixel formation step, firstly, a polysilicon film which is crystallized by an excimer laser and the like is formed on allover the luminous element forming face 30a as shown in FIG. 6. Subsequently, the channel film BC is formed in each pixel forming region 31 by patterning the polysilicon film. After the channel film BC is formed, the gate insulating film D0 made of the silicon oxide film and the like is formed on the whole upper surface of the channel film BC and the luminous element forming face 30a. The low-resistance metal film made of tantalum and the like is then deposited on allover the gate insulating film D0. Subsequently, the gate electrode Pg is formed on the gate insulating film D0 by patterning the low-resistance metal film. After the gate electrode Pg is formed, the n-type region (the source region and the drain region) is formed in the channel film BC by an ion-doping method using the gate electrode Pg as a mask.

After the source region and the drain region is formed in the channel film BC, the transparent conductive film such as the ITO is deposited on the whole upper surface of the gate electrode Pg and the gate insulating film D0. The transparent conductive film is then patterned so as to form the gate wiring M1 on the gate electrode Pg. Following the formation of the gate wiring M1, the first interlayer insulating film D1 made of the silicon oxide film and the like is formed on the whole upper surface of the gate wiring M1 and the gate insulating film D0. A pair of contact holes is patterned in the first interlayer insulating film D1 at the position opposing the source region and the drain region. The source contact Sc and the drain contact Dc are formed by filling the holes with a metal film.

After forming the contacts Sc, Dc, a metal film made of aluminum and the like is deposited on the whole upper surface of the contacts Sc, Dc and the first interlayer insulating film D1. Subsequently, the power wire M2s and the positive electrode line M2d that electrically couple to the contacts Sc, Dc respectively are formed by patterning the metal film. Next, the second interlayer insulating film D2 made of the silicon oxide film and the like is deposited on the whole upper surface of the positive electrode line M2d and the first interlayer insulating film D1. A via hole is then formed in the second interlayer insulating film D2 at a position opposing a part of the positive electrode line M2d. Subsequently, a transparent colorless conductive film made of the ITO and the like is deposited on an inner face of the via hole and the whole upper surface of the second interlayer insulating film D2. The cathode Pc which couples with the positive electrode line M2d is then formed by patterning the transparent conductive film.

After the formation of the cathode Pc, the third interlayer insulating film D3 made of the silicon oxide film and the like is deposited on the whole upper surface of the cathode Pc and the second interlayer insulating film D2. The third interlayer insulating film D3 is then patterned so as to form the position alignment opening D3h with the alignment diameter R1. Following the formation of the position alignment opening D3h, light indurative resin is applied inside the position alignment opening D3h and on the whole upper face of the third interlayer insulating film D3. The partition wall layer DB having the partition wall DBw (conical opening DBh) is formed by patterning the light indurative resin.

A constituent material of the hole transfer layer is discharged into the position alignment opening D3h (conical opening DBh) by the ink-jet method and the like. The hole transfer layer is formed by drying and hardening the constituent material. Furthermore, a constituent material of the emissive layer is discharged on the hole transfer layer by the ink-jet method and the like, and the emissive layer is formed by drying and hardening the constituent material. In other words, the organic EL layer OEL having the diameter of the alignment diameter R1 is formed. After the organic EL layer OEL is formed, the anode Pa made of the metal film such as aluminum is deposited on the whole upper face of the organic EL layer OEL and the third interlayer insulating film D3. Finally, the organic EL element 33 consisting of the cathode Pc, the organic EL layer OEL and the anode Pa is formed. In this way, the pixel 34 having the TFT 32 and the organic EL element 33 is formed.

Throughout the formation process, the element substrate 30 receives a mechanical load by various kinds of the heat treatments and the plasma treatment and so on. However, the element substrate 30 has the before-grinding thickness T0 so that it can avert a mechanical breakage.

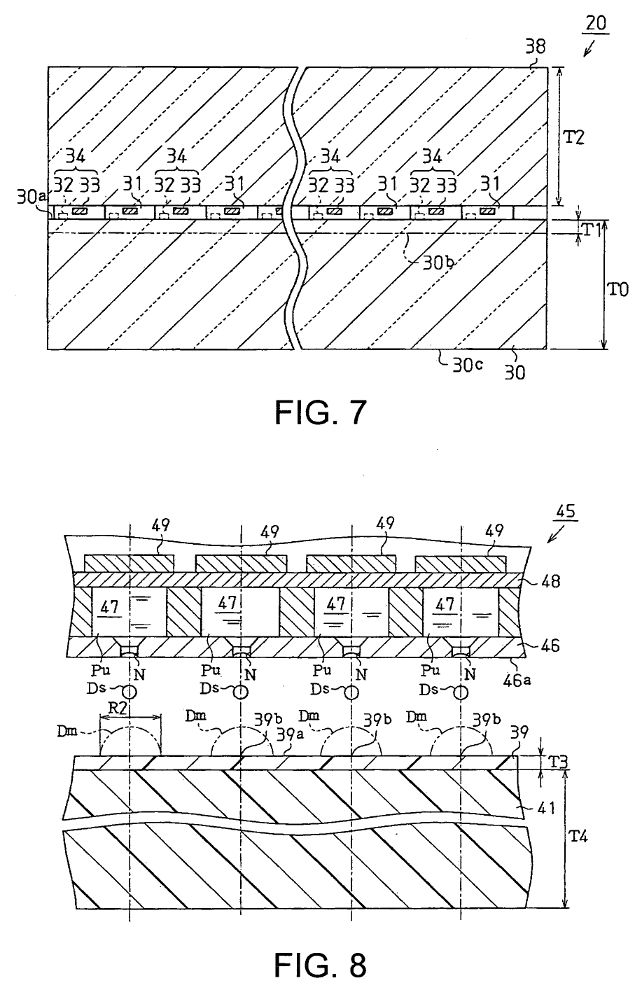

After the pixel 34 is formed on the luminous element forming face 30a, a support substrate attachment step (Step 12 or S12) in which the support substrate 38 is attached to the element substrate 30 is performed as shown in FIG. 5. More specifically, the adhesion layer La1 is formed by applying adhesive made of the epoxy resin and the like on the whole upper surface of the pixel 34 (anode Pa). The support substrate 38 having a thickness of the support thickness T2 (500 μm) is then attached to the element substrate with the adhesion layer La1 therebetween as shown in FIG. 7.

After the element substrate 30 is attached to the support substrate 38, a grinding step (Step 13 or S13) in which the element substrate 30 is grinded is performed as shown in FIG. 5. To be more specific, the support substrate 38 is supported by a support table and the like of an unshown grinding machine. The lateral face (a grinded face 30c) of the element substrate 30 opposing the luminous element forming face 30a is grinded with a grindstone and the like as shown in FIG. 7.

During the above-described process, the element substrate 30 receives a mechanical load by the grindstone and so on. However, the mechanical strength of the element substrate 30 is compensated with the support substrate 38 having the support thickness T2 so that it can avert a mechanical breakage.

After the element substrate 30 is grinded so as to have the after-grinding thickness T1, a droplet discharge step in which droplets are discharged on the above-mentioned sheet substrate 39 is performed (Step 21 or S21) as shown in FIG. 5. FIG. 8 is an explanatory drawing for explaining the manufacturing process of the exposure head. Firstly, structure of a droplet discharge device for discharging the droplets is described.

In this droplet discharge step, a one side of the sheet substrate 39 opposing the lens forming face 39a is attached to a holding substrate 41 with an unshown adhesion layer therebetween as shown in FIG. 8. The adhesion layer is degradable with ultraviolet irradiation and can be removed so that the sheet substrate 39 can be separated from the holding substrate 41. The holding substrate 41 is a flexible substrate made of resin and the like and has a thickness (hold thickness T4) that can prevent the sheet substrate 39 from being bent. Such hold thickness T4 is 1 mm in this embodiment.

A droplet discharge head 45 which is a part of the droplet discharge device has a nozzle plate 46. A nozzle N is formed upward on the inferior surface (a nozzle formed face 46a) of the nozzle plate 46 as shown in FIG. 8. The nozzle N is provided in the plural number and discharges ultraviolet indurative resin Pu which is a functional liquid. A feed chamber 47 is formed above each nozzle N. The feed chamber communicates with an unshown storage tank so that the ultraviolet indurative resin Pu can be supplied into the nozzle N. A vibrating board 48 is provided on each feed chamber 47. The vibrating board 48 vibrates in the vertical direction so as to increase or decrease the volume of the feed chamber 47. A piezoelectric element 49 is provided on the vibrating board 48 at the position opposing each feed chamber 47. The piezoelectric element 49 expands and contracts in the vertical direction in order to vibrate the vibrating board 48.

The sheet substrate 39 (holding substrate 41) is conveyed to the droplet discharge device and placed at the position where the lens forming face 39a opposes the nozzle formed face 46a as shown in FIG. 8. Moreover, the sheet substrate 39 (holding substrate 41) is placed such that the lens forming face 39a becomes parallel with the nozzle formed face 46a and each lens forming position 39b is placed right under the center of the nozzle N.

When a driving signal for discharging the droplet is inputted into the droplet discharge head 45, the piezoelectric element 49 expands and contracts according to the driving signal and the volume of the feed chamber 47 increases and decreases. At this time, if the volume of the feed chamber 47 decreases, the corresponding amount of the ultraviolet indurative resin Pu depending on the decreased volume of the feed chamber 47 is discharged as a minute droplet Ds from each nozzle. Each discharged minute droplet Ds lands at the lens forming position 39b on the lens forming face 39a. Subsequently, if the volume of the feed chamber 47 increases, a certain amount of the ultraviolet indurative resin Pu corresponding to the increased volume of the feed chamber 47 is supplied to the feed chamber 47 from the unshown storage tank. In other words, the droplet discharge head 45 discharges a certain amount of the ultraviolet indurative resin Pu toward the lens forming face 39a by increasing and decreasing the volume of the feed chamber 47. A plurality of the minute droplets Ds landed on the lens forming face 39a forms a droplet Dm that has a semispherical surface by surface tension and the like as shown by the chain-double dashed line in FIG. 8. At this time, the droplet discharge head 45 discharges the minute droplets Ds so as to form the droplet Dm having substantially the same diameter as the aperture diameter R2 of the microlens 40. In other words, the droplet discharge head 45 discharges the minute droplets Ds the minute droplets Ds so as to form the droplet Dm having the diameter of 100 μm.

Surface profile (the hemisphere surface) of each droplet Dm formed on the lens forming face 39a becomes as even as the arithmetic average roughness Ra of the lens forming face 39a which is less than 1 μm. After the formation of the droplet Dm on the lens forming face 39a, a lens formation step (Step 22 or S22) in which the lens is formed by hardening the droplet Dm is performed as shown in FIG. 5. More specifically, the droplet Dm (the lens forming face 39a) is irradiated with ultraviolet and gets harden. In this way, the microlens 40 having the aperture diameter R2 is formed at the lens forming position 39b on the sheet substrate 39.

After the microlens 40 is formed on the sheet substrate 39, a separation step (Step 23 or S23) in which the sheet substrate 39 is separated from the holding substrate 41 is performed as shown in FIG. 5. To be more specific, when the sheet substrate 39 is irradiated with the ultraviolet in the above-mentioned lens formation step, the sheet substrate 39 attached on the holding substrate 41 becomes smoothly separable from the holding substrate 41. The sheet substrate 39 having the microlens 40 is then separated from the holding substrate 41 by an unshown separation machine.

Following the separation of the sheet substrate 39 from the holding substrate 41, a sheet substrate attachment step (Step 14 or S14) in which the sheet substrate 39 is adhered to the element substrate is performed as shown in FIG. 5. More specifically, an adhesion made of the ultraviolet curing resin is printed on the attach face 30b by a squeegee printing method and the adhesion layer La2 is formed. The sheet substrate 39 is then attached such that each lens forming position 39b opposes the center of the organic EL layer OEL. The sheet substrate 39 (the adhesion layer La2) is subsequently irradiated with ultraviolet and the adhesion layer La2 is hardened.

As described above, the aperture angle θ1 of the microlens 40 can be increased since the distance between the luminous element forming face 30a and the lens forming face 39a (the sum of the after-grinding thickness T1 and the sheet thickness T3) decreases by the distance between the luminous element forming face 30a and the grinded face 30c, which is 400 Jm. Accordingly, the amount of the light emitted from the emission face 40a of the microlens 40 can be increased and the light takeoff efficiency of the light emitted from the organic EL element 33.

As described above, the exposure head 20 having the uniform microlens 40 of the aperture diameter R2 (100 μm) on the element substrate 30 of the after-grinding thickness T1 (50 μm) with the sheet substrate 39 of the sheet thickness T3 therebetween can be manufactured.

Next, advantageous effects of the embodiment described above are described.

(1) According to the embodiment, the attach face 30b is formed by grinding the grinded face 30c of the element substrate 30 having the pixel 34 and the support substrate 38 (S13), the microlens 40 is formed on the lens forming face 39a of the sheet substrate 39 (S22), and then, the sheet substrate 39 having the microlens 40 is attached on the attach face 30b of the element substrate 30. Thereby, the aperture angle θ1 of the microlens 40 can be increased by the grinding of the element substrate 30, and it is possible to manufacture the exposure head 20 in which the light takeoff efficiency of the light emitted from the organic EL element 33 is increased.

(2) According to the embodiment, the microlens 40 is formed on the lens forming face 39a whose arithmetic average roughness Ra is less than 1 μm. Therefore, comparing with a case that the microlens 40 is formed on the attach face 30b which is formed by grinding, the feature size of the microlens 40 can be more uniform.

(3) According to the above-described embodiment, the droplet Dm is formed on the lens forming face 39a held by the holding substrate 41 and the microlens 40 is formed by irradiating the droplet Dm with ultraviolet. Therefore, the microlens 40 can be formed without any limitation for the thickness of the element substrate 30. As a result, the after-grinding thickness T1 of the element substrate 30 can be set according to a machining performance of the grinding process and it is possible to further improve the light takeoff efficiency of the exposure head 20.

(4) Furthermore, the microlens 40 is formed without irradiating the element substrate 30 with ultraviolet so that it can prevent the organic EL element 33 from being damaged by the ultraviolet irradiation and the light takeoff efficiency of the exposure head 20 can be improved.

The above-described embodiment may be modified as hereinafter described.

The sheet substrate 39 is attached on the attach face 30b of the element substrate 30 after the microlens 40 is formed on the sheet substrate 39 (Step 22) in the above-described embodiment. However, the sheet substrate 39 may firstly be attached on the attach face 30b of the element substrate 30, and then the microlens 40 may be formed on the lens forming face 39a of the sheet substrate 39.

Though the element substrate 30 is mechanically grinded so as to have the thickness of the after-grinding thickness T1 in the above-described embodiment, the way to grind the grinded face 30c toward the luminous element forming face 30a is not particularly limited. For example, the element substrate 30 may be dipped in a diluted fluorinated acid solution, a mixture solution of the diluted fluorinated acid and ammonium fluoride or a mixture solution of hydrochloric acid and nitric acid so that the grinded face 30c of the element substrate 30 is etched to have the after-grinding thickness T1. It is preferable that the after-grinding thickness T1 is set to be the least thickness at which the thickness of the element substrate 30 becomes uniform by the etching and the like.

In the above-described embodiment, the droplet Dm is formed by discharging the ultraviolet indurative resin Pu onto the attach face 30b formed in the grinding step. Moreover, the surface of the attach face 30b may be treated with a water repellant finishing (for example, a fluorinated series plasma treatment, an application of a hydrophobic material and the like) before the droplet Dm is formed by discharging the ultraviolet indurative resin Pu. In this way, it is possible to easily form the droplet Dm having the semispherical surface without letting the minute droplets Ds spread out.

Though the transparent substrate is the element substrate 30 in the above-described embodiment, the transparent substrate is not especially limited as long as it can transmit the light emitted from the organic EL layer OEL. For example, it may be a plastic substrate made of polyimide and the like.

The sheet substrate 39 is the polyimide sheet in the above-described embodiment. However, it is not particularly limited as long as the arithmetic average roughness Ra of the lens forming face 39a is smaller than the arithmetic average roughness Ra of the attach face 30b. For example, the sheet substrate 39 may be a polystyrene sheet.

Though the aperture diameter R2 of the microlens 40 is twice as large as the inner diameter (the alignment diameter R1) of the organic EL layer OEL, it is not especially limited as long as it will not impair the imaging quality around the peripheral of the microlens 40 and it can form the exposure spot with a desired size corresponding to each organic EL layer OEL. For example, the aperture diameter R2 may be as large as the alignment diameter R1.

The microlens 40 is the convex shape lens having the hemispherical surface in the above-described embodiment. However, it is not limited to this. For example, the microlens 40 may be a half-column shaped lens or a concave lens. In this way, it is possible to further improve a diffusing efficiency of the light emitted from the organic EL element 33.

Though the microlens 40 is made of the ultraviolet indurative resin Pu in the above-described embodiment, it is not limited a long as it is a functional liquid that is indurative on the lens forming face 39a. For example, the microlens 40 may be made of a thermo-setting resin.

The image side focal length Hf is the distance between the top of the emission face 40a and the photosensitive layer 16a so that the light emitted from the organic EL layer OEL can be focused on the lens forming face 39a in the above-described embodiment. However, the case is not especially limited to this image side focal length Hf. The distance between the top of the emission face 40a and the photosensitive layer 16a may be, for example, a distance at which the image of the same magnification is obtained.

Though the microlens 40 is formed by the droplet discharge device in the above-described embodiment, the case is not limited to this. For example, the microlens 40 formed by, for example, using a replica technique may be attached to the lens forming position 39b.

In the above-described embodiment, the one TFT 32 controlling the light emission of the organic EL element 33 is provided at the every one pixel 34. However, more than one TFT 32 controlling the light emission of the organic EL element 33 may be provided at the every one pixel 34 or the TFT 32 may not be provided on the element substrate 30.

Though the organic EL layer OEL is formed by the ink-get method in the above-described embodiment, the forming method of the organic EL layer OEL is not particularly limited. For example, it may be a spin-coat method, a vacuum deposition method and the like.

The organic EL layer OEL is made of a kind of the polymer organic material in the above-described embodiment. However, the organic EL layer OEL may be an EL layer made of a low-molecular organic material or an inorganic material.

In the above-described embodiment, the electrooptical device is the exposure head 20. However, the electrooptical device is not limited to this. For example, there are a back light equipped with a liquid crystal panel, a field effect type display (a field emission display [FED], a surface-conduction electron-emitter display [SED] and the like) having an electron emission element in planar shape and utilizing an emission of a fluorescent substance by the electron released from the element, and so on.

What is claimed is:

1. A method of manufacturing an electrooptical device, comprising:
forming a luminous element on a luminous element forming face of a transparent substrate;
forming an attach face by grinding a face of the transparent substrate that opposes the luminous element forming face toward the luminous element forming face side after attaching a support substrate to the transparent substrate on the luminous element forming face side; and
providing a microlens that sends out a light emitted from the luminous element on the transparent substrate with a sheet substrate therebetween by attaching a side face of the sheet substrate opposing a lens forming face on which the microlens is formed to the attach face.

2. The method of manufacturing an electrooptical device according to claim 1, wherein the microlens is provided on the transparent substrate by attaching the side face of the sheet substrate to the attach face after the microlens is formed on the lens forming face of the sheet substrate.

3. The method of manufacturing an electrooptical device according to claim 2, wherein the microlens is provided in a plural number and formed on the lens forming face, each microlens is placed so as to oppose the corresponding luminous element by attaching the side face of the sheet substrate to the attach face.

4. The method of manufacturing an electrooptical device according to claim 1, wherein the attach face is formed by grinding the face of the transparent substrate.

5. The method of manufacturing an electrooptical device according to claim 1, wherein the attach face is formed by etching the face of the transparent substrate.

6. The method of manufacturing an electrooptical device according to claim 1, wherein a droplet is formed on the lens forming face by discharging functional liquid from a droplet discharge device, and the microlens is formed by indurating the droplet.

7. The method of manufacturing an electrooptical device according to claim 6, wherein the droplet having a semispherical shape is formed on the lens forming face at a position opposing the luminous element, and the convex shaped microlens is formed by indurating the droplet.

8. The method of manufacturing an electrooptical device according to claim 1, wherein the luminous element is an electroluminescence element having a transparent electrode formed on the attach face side, a back electrode formed so as to oppose the transparent electrode, and an emissive layer formed between the transparent electrode and the back electrode.

9. The method of manufacturing an electrooptical device according to claim 8, wherein the emissive layer is made of an organic material and the electroluminescence element is an organic electroluminescence element.

10. An image forming device, comprising:
a charge unit charging a peripheral surface of an image retainer;
an exposure unit exposing the charged peripheral surface of the image retainer and forming a latent image;
a develop unit developing the image into a developed image by supplying a colored particle to the latent image; and
a transfer unit transferring the developed image to a transfer medium, wherein the exposure unit is the electrooptical device according to claim 1.
